(19) United States
(12) Patent Application Publication
(10) Pub. No.: US 2026/0211050 A1
(43) Pub. Date: Jul. 23, 2026

(54) SYSTEMS AND METHODS OPERABLE FOR MONITORING STATE OF CHARGE OF BATTERIES

(71) Applicant: O2Micro Inc., Santa Clara, CA (US)

(72) Inventors: Sterling DU, Palo Alto, CA (US); Zhiguo LIU, Chengdu (CN); Heng YANG, Wuhan (CN); Qi CHEN, Wuhan (CN)

(21) Appl. No.: 19/454,112

(22) Filed: Jan. 20, 2026

Related U.S. Application Data
(60) Provisional application No. 63/747,330, filed on Jan. 20, 2025.

(30) Foreign Application Priority Data
Dec. 19, 2025 (CN) 202511937801.5

(51) Int. Cl. G01R 31/389; G01R 31/367; G01R 31/374; G01R 31/3842; G01R 31/392; H01M 10/42

(52) U.S. Cl. CPC G01R 31/389; G01R 31/367; G01R 31/374; G01R 31/3842; G01R 31/392; H01M 10/4285

(57) ABSTRACT

In a battery monitoring system, a stimulus circuit applies a stimulus signal to a battery. A sampling circuit synchronously samples a voltage and a current, associated with the battery, at a sampling frequency to obtain a set of voltage values and a set of current values. A storage unit stores multiple datasets, each of which includes a frequency value, an imaginary impedance value, and an SOC value. A processing unit determines an imaginary part of the battery's impedance, corresponding to a stimulus frequency carried in the stimulus signal, based on the voltage values and the current values, and searches the multiple datasets for one or more matched datasets. The frequency value and the imaginary impedance value in the matched dataset “match” the stimulus frequency and the imaginary part, respectively. The processing unit determines a reference value of the battery's SOC based on the SOC value in the matched dataset.

### RELATED APPLICATIONS

This application claims priority to the U.S. Provisional Application with Ser. No. 63/747,330, filed on Jan. 20, 2025, and claims benefit under 35 U.S.C. § 119(a) to application No. 202511937801.5, filed with the State Intellectual Property Office of the People's Republic of China on Dec. 19, 2025, which are hereby incorporated by reference in their entirety.

### BACKGROUND

Rechargeable batteries are widely used in daily appliances and devices such as mobile phones, laptops, tablets, electric bicycles, electric vehicles, power banks, and backup power systems. Battery safety is a critical concern, as failures can lead to fires or explosions. Battery safety is closely managed by monitoring the battery's state of health (SOH), which reflects its degradation level, and its state of charge (SOC), which reflects its remaining charge level. An abnormal change in the SOC may indicate a low level of the SOH. Both SOH and SOC are key parameters used by battery management systems to ensure safe operation.

A conventional method for estimating an SOC of a battery includes a coulomb integration method combined with an open-circuit voltage method. This method can provide an estimated value of the SOC that reflects the actual SOC of the battery if the battery is in a healthy state. However, if the battery is not in a healthy state, a deviation of the estimated value from the actual SOC may be relatively large.

A conventional method for estimating the battery's actual SOC and monitoring the battery's SOH includes using an electrochemical technique called “electrochemical impedance spectroscopy (EIS).” In this technique, a small-amplitude alternating-current (AC) signal is applied to the battery, and a corresponding current or voltage response of the battery is measured. The measured response is used to determine the battery's complex impedance at different frequencies. By applying AC signals across a wide frequency range, multiple impedance values (including real components, imaginary components, impedance magnitudes, and/or phase angles) can be obtained. These values can be represented by EIS plots, such as a Nyquist plot (real part vs. imaginary part), a Bode magnitude plot (impedance magnitude vs. frequency), and a Bode phase plot (phase angle vs. frequency). For a healthy battery, these plots exhibit distinctive, reproducible patterns. Deviations from these patterns can indicate changes in SOH, and correlations between impedance features and charge storage characteristics can be used to estimate SOC. However, this technique requires applying AC signals over a relatively large frequency range, e.g., from 0.01 Hz to 100 kHz, and performing computationally intensive analysis to generate real-time EIS data and compare the real-time EIS data to reference modes. Consequently, it may demand significant computing resources and be relatively power consuming.

### SUMMARY

Embodiments according to the present invention provide systems and methods for monitoring an SOC of a battery based on an imaginary part of an impedance of the battery.

In an embodiment, a battery monitoring system includes a stimulus circuit, a sampling circuit, a non-transitory machine-readable storage medium, and a processing unit. The stimulus circuit can apply a stimulus signal to a battery. The stimulus signal includes information for a periodic signal having a stimulus frequency. The sampling circuit can synchronously sample a battery-related voltage and a battery-related current at a sampling frequency to obtain a set of voltage values and a set of current values. The sampling frequency is higher than the stimulus frequency. The battery-related voltage and the battery-related current are associated with the battery and vary in response to the stimulus signal. The non-transitory machine-readable storage medium can store multiple datasets. Each dataset includes a frequency value, an imaginary impedance value, and an SOC value. The processing unit can determine an imaginary part of an impedance of the battery based on the voltage values and the current values, and search the multiple datasets for one or more matched datasets. The frequency value in a matched dataset “matches” (e.g., is selected as a match for) the stimulus frequency, and the imaginary impedance value in the matched dataset matches (e.g., is selected as a match for) the imaginary part of the impedance of the battery. The processing unit can also determine a reference value of an SOC of the battery based on the SOC value in the matched dataset. The reference value of the SOC can be used to enhance the accuracy of estimating the battery's SOC and evaluate the battery's SOH. Additionally, determining the reference value of the SOC requires relatively few computing resources, thereby reducing the system's power consumption.

### BRIEF DESCRIPTION OF THE DRAWINGS

Features and advantages of embodiments of the claimed subject matter will become apparent as the following detailed description proceeds, and upon reference to the drawings, wherein like numerals depict like parts, and in which:

FIG. 1 illustrates a block diagram of an example of a battery monitoring system, in an embodiment of the present invention.

FIG. 2 illustrates a set of Nyquist plots generated by an example of a battery monitoring system at different SOCs of the battery, in an embodiment of the present invention.

FIG. 3 illustrates a set of imaginary impedance vs. frequency plots generated by an example of a battery monitoring system at different SOCs of a battery, in an embodiment of the present invention.

FIG. 4 illustrates a set of imaginary impedance vs. frequency plots generated by an example of a battery monitoring system at different SOCs of a battery, in an embodiment of the present invention.

FIG. 5A illustrates a flowchart of an example of a method for monitoring an SOC of a battery, in an embodiment of the present invention.

FIG. 5B illustrates a flowchart of an example of a method for monitoring an SOC of a battery, in an embodiment of the present invention.

FIG. 6 illustrates a flowchart of an example of a method for monitoring an SOC of a battery, in an embodiment of the present invention.

FIG. 7 illustrates a flowchart of an example of a method for monitoring an SOC of a battery, in an embodiment of the present invention.

FIG. 8 illustrates a flowchart of an example of a method for monitoring an SOC of a battery, in an embodiment of the present invention.

### DETAILED DESCRIPTION

Reference will now be made in detail to the various embodiments of the present disclosure, examples of which are illustrated in the accompanying drawings. While described in conjunction with these embodiments, they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, the present disclosure may be practiced without these specific details. In other instances, well-known methods, procedures, components, and circuits have not been described in detail so as not to unnecessarily obscure aspects of the present disclosure.

Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computer system. It has proven convenient at times, principally for reasons of common usage, to refer to these signals as transactions, bits, values, elements, symbols, characters, samples, pixels, or the like.

It should be borne in mind, however, that all of these and similar terms are to be associated with the appropriate physical quantities and are merely convenient labels applied to these quantities. Unless specifically stated otherwise as apparent from the following discussions, throughout the present disclosure, discussions utilizing terms such as “determining,” “searching,” “calculating,” “extracting,” “estimating,” “storing,” “applying,” “sampling,” or the like, may refer to actions and processes of and executed by an apparatus or computer system or similar electronic computing device or processor. A computer system or similar electronic computing device manipulates and transforms data represented as physical (electronic) quantities within memories, registers or other such information storage, transmission or display devices. In its most basic configuration, a computer system or the like includes at least one processing unit and memory. The computer system may also have additional features and/or functionality, such as the capability for communicating with other devices, the capability to receive user inputs, and the capability to display results.

Embodiments described herein may be discussed in the general context of computer-executable instructions residing on some form of computer-readable storage medium, such as modules, executed by one or more computers, other devices, or circuits. By way of example, and not limitation, computer-readable storage media may comprise non-transitory computer storage media and communication media. Generally, modules may include software, routines, programs, objects, components, data structures, etc., that perform particular tasks or implement particular abstract data types. The functionality of the modules may be combined or distributed as desired in various embodiments. Modules may also be implemented using circuits such as an acquisition circuit or a processing circuit (e.g., a chip or a processor). Moreover, the modules are merely logical modules defined based on specific functions implemented by the modules and are not intended to limit an implementation. For example, a module may be implemented by one or more application-specific integrated circuits, software programs, or a combination thereof.

Computer storage media includes volatile and nonvolatile, removable and non-removable media implemented in any method or technology for storage of information such as computer-readable instructions, data structures, program modules or other data. Computer storage media includes, but is not limited to, random access memory (RAM), read only memory (ROM), electrically erasable programmable ROM (EEPROM), flash memory (e.g., an SSD) or other memory technology, compact disk ROM (CD-ROM), digital versatile disks (DVDs) or other optical storage, magnetic cassettes, magnetic tape, magnetic disk storage or other magnetic storage devices, or any other medium that can be used to store the desired information and that can accessed to retrieve that information.

Communication media may embody computer-executable instructions, data structures, and modules, and includes any information delivery media. By way of example, and not limitation, communication media may include wired media such as a wired network or direct-wired connection, and wireless media such as acoustic, radio frequency (RF), infrared and other wireless media. Combinations of any of the above can also be included within the scope of computer-readable media.

As used herein, the term “parameter” or the like may be the name of a property or metric (e.g., “voltage”) or the numerical value of that property or metric (e.g., 5 volts). A person of ordinary skill in the art will understand how the term is being used.

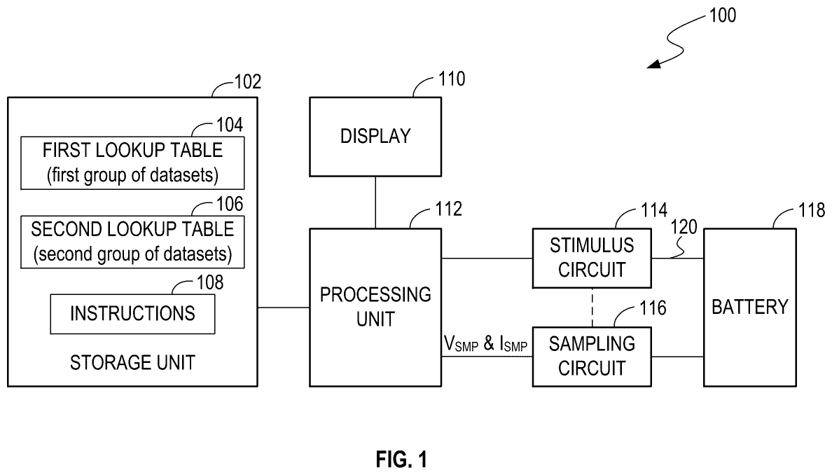

As discussed in the background above, battery safety is a critical concern, as failures can lead to fires or explosions. Battery safety is closely managed by monitoring the battery's state of health (SOH), which reflects its degradation level, and its state of charge (SOC), which reflects its remaining charge level. An abnormal change in the SOC may indicate a low level of the SOH. Embodiments according to the presently disclosed invention are integrated into a practical application of accurately and efficiently calculating SOC and evaluating SOH. More specifically, these embodiments improve the accuracy of the SOC value while also improving the performance of a battery-powered electronic device (specifically, the computing/processing circuitry used by the device to calculate the SOC; e.g., see FIG. 1) by reducing the computational resources consumed during the SOC calculation, thereby also reducing the amount of power (electricity) used by the device to perform the SOC calculation. Reducing power consumption is an important consideration in battery-powered electronic devices. These embodiments also evaluate the SOH based on the calculated SOC to ensure battery safety. The ranges of values of the parameters used to calculate SOC, and the various combinations of those parameters and their values, can complicate the calculation of SOC; therefore, accurate, quick, and efficient calculations of SOC is beyond the capability of a human and relies on the use of a computing system or the like (e.g., FIG. 1), particularly considering the time constraints associated with determining SOC in real time.

FIG. 1 illustrates a block diagram of an example of a battery monitoring system 100, in an embodiment of the present invention. The battery monitoring system 100 can include a storage unit 102, a display 110, a processing unit 112, a stimulus circuit 114, a sampling circuit 116, and a battery 118. The battery 118 can include one or more rechargeable battery cells. The storage unit 102, e.g., a non-transitory machine-readable storage medium, can store computer-executable instructions 108. The instructions 108, when executed by the processing unit 112, can cause the processing unit 112 to control the stimulus circuit 114 to apply a stimulus signal 120 to the battery 118, control the sampling circuit 116 to sample and/or monitor parameters (e.g., including a voltage, a current, a temperature, etc.) of the battery 118, estimate a state of charge (SOC) of the battery 118 based on the parameters, and control the display 110 to show the SOC in percentage form to a user.

In some embodiments, the stimulus circuit 114 can generate and apply a stimulus signal 120 to the battery 118. The stimulus signal 120 can include information for a periodic signal, e.g., a sinusoidal signal, having a stimulus frequency F_{STML}. In some embodiments, the stimulus signal 120 can include a signal selected from the group consisting of a sinusoidal signal, a DC-biased (direct-current-biased) sinusoidal signal, a multisine signal, a DC-biased multisine signal, a square-wave signal, a pseudo-random binary sequence (PRBS) signal, a chirp signal, and white noise. For example, the stimulus signal 120 can be a sinusoidal signal or a DC-biased sinusoidal signal having a predetermined frequency. For some other examples, the stimulus signal 120 can be a signal such as a multisine signal, a DC-biased multisine signal, a square-wave signal, a PRBS signal, a chirp signal, or white noise that, when decomposed (e.g., using Fourier transform), includes multiple frequency components. Each of the frequency components can be represented by a sinusoidal signal having a corresponding frequency. In an embodiment, the abovementioned periodic signal having the stimulus frequency F_{STML} can be selected from among the frequency components. Detailed explanations for the multisine signal, DC-biased multisine signal, square-wave signal, PRBS signal, chirp signal, white noise, and Fourier transform are available in the known art and so are not included herein.

In some embodiments, the sampling circuit 116 synchronously samples a battery-related voltage and a battery-related current at a sampling frequency F_{SMP} to obtain a set of voltage values V_{SMP} and a set of current values I_{SMP}. The sampling frequency F_{SMP} is greater than the stimulus frequency F_{STML}. In other words, the sampling circuit 116 can sample the battery-related voltage and battery-related current multiple times to obtain a set of voltage values V_{SMP} and a set of current values I_{SMP}, and the sampling frequency is set to an F_{SMP} that is greater than the stimulus frequency F_{STML}. The battery-related voltage and battery-related current are associated with the battery 118, and can vary in response to the stimulus signal 120. As used herein, “synchronously” means that the measurements of the battery-related voltage and battery-related current are performed concurrently or contemporaneously, or are considered to be performed concurrently or contemporaneously. As used herein, “considered to be performed concurrently or contemporaneously” means that the battery-related voltage may be measured at time A, the battery-related current may be measured at time B, and a calculation is performed based on the battery-related voltage to generate a calculated voltage value such that the calculated voltage value is considered to be a value of the battery-related voltage measured at time B. The processing unit 112 can receive the information for the voltage values V_{SMP} and current values I_{SMP}, and determine a reference value S_{REF} of a state of charge (SOC) of the battery 118 based on the voltage values V_{SMP} and current values I_{SMP}. In some embodiments, the reference value S_{REF} can be used to enhance the accuracy of estimating the battery's SOC and evaluate the battery's SOH.

More specifically, in some embodiments, the stimulus signal 120 includes a stimulus current, e.g., a sinusoidal current, a DC-biased sinusoidal current, a multisine current, a DC-biased multisine current, a square-wave current, a PRBS current, a chirp current, or a white-noise current. For example, the stimulus circuit 114 can include a current source coupled to the battery 118 and configured to generate a stimulus current to flow through the battery 118. The real-time voltage and real-time current of the battery 118 can vary in response to the stimulus current. The response of the real-time voltage and current can be measured by synchronously sampling the real-time voltage and real-time current of the battery 118 or by synchronously sampling the real-time voltage of the battery 118 and the stimulus current. In an embodiment, the abovementioned battery-related voltage sampled by the sampling circuit 114 includes a battery voltage of the battery 118. The battery 118 may include one or more battery cells coupled in series. The battery voltage of the battery 118 can include a voltage of a single cell or a total voltage of all cells. Additionally, in an embodiment, the abovementioned battery-related current sampled by the sampling circuit 114 is a battery current, e.g., a charge current or a discharge current, of the battery 118. Because the stimulus current flows through the battery 118, the battery current of the battery 118 includes the stimulus current. In an alternative embodiment, the abovementioned battery-related current sampled by the sampling circuit 114 is the stimulus current. In other words, the response of the battery current can be measured by sampling the battery current (including the stimulus current) or the stimulus current (without the battery current).

In some embodiments, the stimulus current can be a continuous current during a time window in which the battery-related voltage and battery-related current are sampled at the sampling frequency F_{SMP}. In this time window, the stimulus current carries information for an abovementioned periodic signal having the stimulus frequency F_{STML}. However, power consumption of the stimulus circuit 114 can be relatively high when the stimulus current is continuous. Thus, in some other embodiments, the stimulus circuit 114 can alternately enable and disable the current source (e.g., at the sampling frequency F_{SMP}) to generate a discontinuous stimulus current. The discontinuous stimulus current can still carry information corresponding to the periodic signal. The sampling circuit 116 can sample the battery-related voltage and battery-related current when the current source is enabled. As a result, the power consumption of the stimulus circuit 114 can be reduced.

In some other embodiments, the stimulus signal 120 includes a stimulus voltage, e.g., a sinusoidal voltage, a DC-biased sinusoidal voltage, a multisine voltage, a DC-biased multisine voltage, a square-wave voltage, a PRBS voltage, a chirp voltage, or a white-noise voltage. For example, the stimulus circuit 114 can include a voltage source coupled to the battery 118 and configured to generate a stimulus voltage to apply to the battery 118. In one scenario, a charger can be charging the battery 118 in a constant-voltage mode. The voltage source may be coupled between the charger and the battery 118, superposing the stimulus voltage onto the charging voltage. As a result, the battery volage can vary in response to the stimulus voltage. In another scenario, the battery 118 may be in a shutdown mode, a sleep mode, or fully charged where it is neither charging nor discharging. The voltage source may be coupled between the anode and cathode of the battery 118 and apply the stimulus voltage, e.g., a DC-biased sinusoidal voltage, a DC-biased multisine voltage, or the like, between the anode and cathode of the battery. The real-time voltage and real-time current of the battery 118 can vary in response to the stimulus voltage. The response of the real-time voltage and current can be measured by synchronously sampling the real-time voltage and real-time current of the battery 118 or synchronously sampling the stimulus voltage and the real-time current of the battery 118. In an embodiment, the abovementioned battery-related current sampled by the sampling circuit 114 includes a battery current of the battery 118. Additionally, in an embodiment, the abovementioned battery-related voltage sampled by the sampling circuit 114 is the battery voltage of the battery 118 with the stimulus voltage superposed on it. In another embodiment, the abovementioned battery-related voltage sampled by the sampling circuit 114 is the stimulus voltage. In other words, the response of the battery voltage can be measured by sampling the battery voltage (with the stimulus voltage superposed on it) or the stimulus voltage (without the battery voltage).

In some embodiments, an impedance of the battery 118 (e.g., the impedance of a single cell, the impedance of multiple (e.g., selected) cells, or the total impedance of all cells) can be calculated based on the measured response of the real-time voltage and current of the battery 118. The calculation can be implemented using any known technique, such as methods using magnitude and phase (polar coordinates) or methods based on a Fourier transform. The processing unit 112 can calculate the battery's impedance based on the abovementioned voltage values V_{SMP} and current values I_{SMP}.

In some embodiments, the stimulus circuit 114 can vary the frequency F_{STML} carried in the stimulus signal 120 over a frequency range. This allows the processing unit 112 to generate a Nyquist plot-showing the imaginary part of the impedance versus the real part of the impedance-across that frequency range. In a Nyquist plot, each point can represent a complex impedance (with its real and imaginary components) at a specific frequency. The processing unit 112 and the stimulus circuit 114 can repeat this procedure at different SOCs of the battery 118, enabling the processing unit 112 to generate a set of Nyquist plots, each corresponding to a respective SOC.

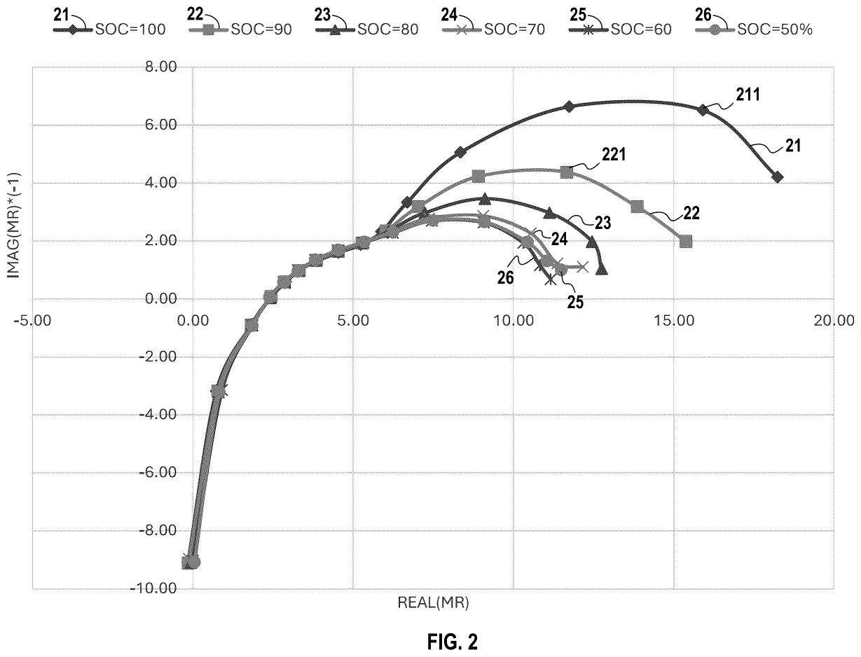

FIG. 2 illustrates a set of Nyquist plots 21 to 26 generated by an example of the battery monitoring system 100 at different SOCs of the battery 118, in an embodiment of the present invention. FIG. 2 is described in combination with FIG. 1. As shown in FIG. 2, Nyquist plots 21, 22, 23, 24, 25, and 26 correspond to SOCs of, for example, 100%, 90%, 80%, 70%, 60%, and 50%, respectively. Although FIG. 2 shows Nyquist plots corresponding to the SOCs that are greater than or equal to 50%, the invention is not so limited. The battery monitoring system 100 can also generate Nyquist plots corresponding to SOCs that are less than 50%.

In the example of FIG. 2, each point of the Nyquist plots 21 to 26 can represent a complex impedance of the battery 118, given by: Z=a+bi, where “Z” represents the impedance, “a” represents the real part of the impedance, “b” represents the imaginary part of the impedance, and “i” represents the imaginary unit (i²=−1). For instance, data point 211 on the 100% SOC Nyquist plot 21 can represent a complex impedance of 6.5+16i. Similarly, data point 221 on the 90% SOC Nyquist plot 22 can represent a complex impedance of 4.5+12i. In addition, each complex impedance on the Nyquist plots 21 to 26 is measured at a specific stimulus frequency. This frequency information is not shown in FIG. 2. In some embodiments, a real part of an impedance can be referred to as a real impedance, and an imaginary part of an impedance can be referred to as an imaginary impedance. Additionally, the complex impedance of the battery 118 can also be given by: Z=R+jX, where “Z” represents the impedance, “R” represents the resistance of the battery 118, “X” represents the reactance of the battery 118, and j represents the imaginary unit. In other words, a real part of a battery's impedance can also be referred to as a resistance of the battery, and an imaginary part of the battery's impedance can also be referred to as a reactance of the battery.

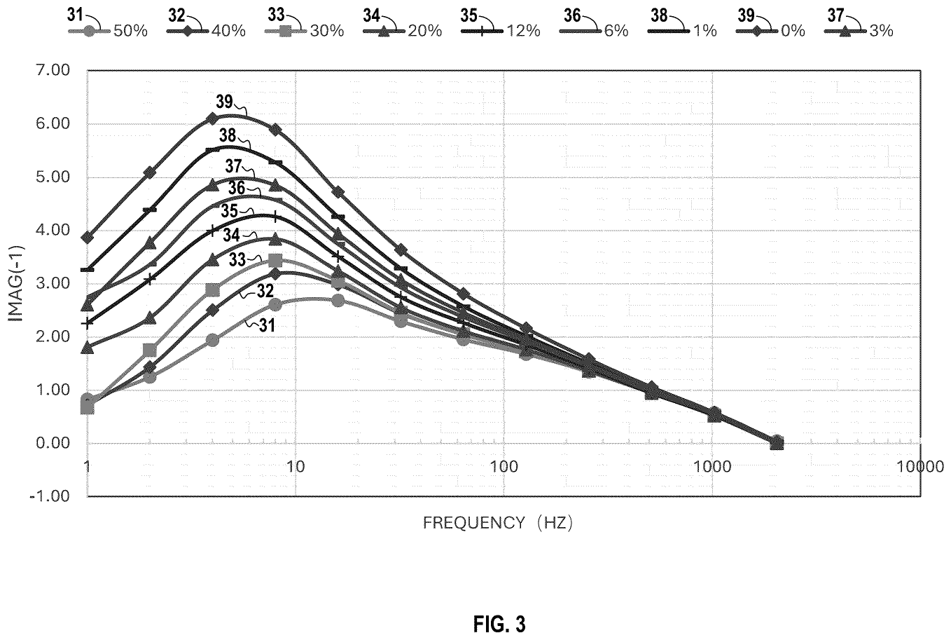

In some embodiments, the processing unit 112 extracts the imaginary parts from the measured complex impedance to generate a set of imaginary impedance vs. frequency plots. FIG. 3 illustrates a set of imaginary impedance vs. frequency plots 31 to 39 generated by an example of the battery monitoring system 100 at different SOCs of the battery 118, in an embodiment of the present invention. FIG. 3 is described in combination with FIG. 1 and FIG. 2.

In the example of FIG. 3, the SOCs are less than or equal to 50%. More specifically, plots 31, 32, 33, 34, 35, 36, 37, 38, and 39 in FIG. 3 correspond to SOCs of 50%, 40%, 30%, 20%, 12%, 6%, 3%, 1%, and 0%, respectively. According to FIG. 3, at a frequency equal to or lower than 10 Hz, the SOC exhibits a relationship with the imaginary impedance. Specifically, for SOCs equal to or less than 50%, the imaginary impedance increases as the SOC decreases. In some embodiments, this relationship between the SOC and the imaginary impedance can be defined by a first lookup table 104 stored in the storage unit 102.

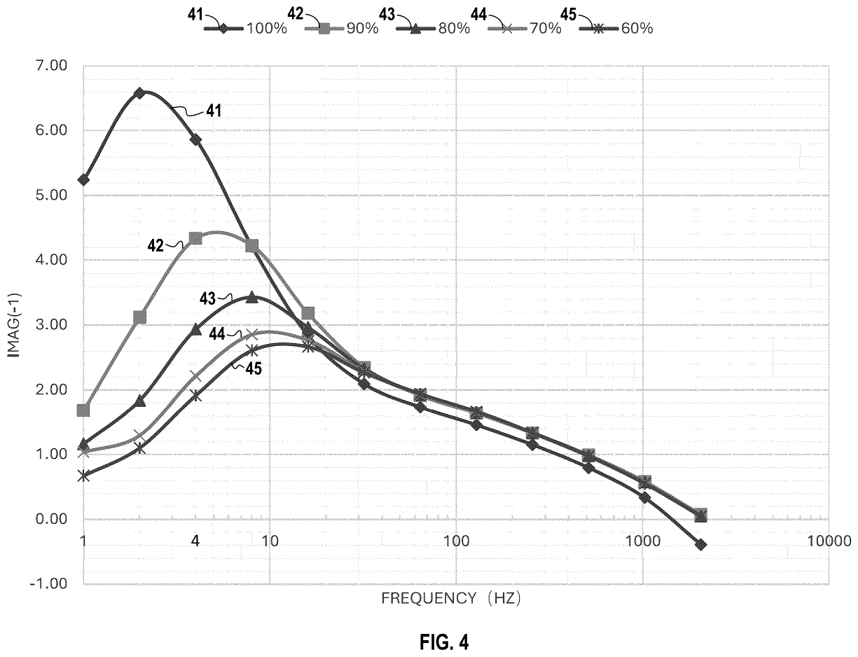

Similarly, FIG. 4 illustrates a set of imaginary impedance vs. frequency plots 41 to 46 generated by an example of the battery monitoring system 100 at different SOCs of the battery 118, in an embodiment of the present invention. FIG. 4 is described in combination with FIG. 1, FIG. 2, and FIG. 3. In the example of FIG. 4, the SOCs are greater than 50%. More specifically, plots 41, 42, 43, 44, and 45 in FIG. 4 correspond to SOCs of 100%, 90%, 80%, 70%, and 60%, respectively. According to FIG. 4, at a frequency equal to or lower than 4 Hz, the SOC exhibits a relationship with the imaginary impedance. Specifically, for SOCs greater than 50%, the imaginary impedance increases as the SOC increases. In some embodiments, this relationship between the SOC and the imaginary impedance can be defined by a second lookup table 106 stored in the storage unit 102.

For example, as shown in FIG. 1, the storage unit 102 can store a first lookup table 104 and a second lookup table 106. The first lookup table 104 includes a first group of datasets. The second lookup table 106 includes a second group of datasets. Each dataset of the first and second group of datasets includes a frequency value F, an imaginary impedance value X, and an SOC value S, and can be represented by (F, X, S). SOC values in the first group of datasets are in a first range. SOC values in the second group of datasets are in a second range. The minimum SOC value of the second range is greater than the maximum SOC value of the first range. In some embodiments, the minimum SOC value of the second range is greater than 50%, and the maximum SOC value of the first range is equal to or less than 50%. For example, the first range can be 0% to 50%, 0% to 40%, 0% to 45%, or the like; and the second range can be 60% to 100%, 55% to 100%, 51% to 100%, or the like. Within the first group of datasets, if the imaginary impedance value in a dataset (e.g., a first dataset) is greater than the imaginary impedance value in another dataset (e.g., a second dataset), then the SOC value in the first dataset is less than the SOC value in the second dataset. Within the second group of datasets, if the imaginary impedance value in a dataset (e.g., a third dataset) is greater than the imaginary impedance value in another dataset (e.g., a fourth dataset), then the SOC value in the third dataset is greater than the SOC value in the fourth dataset.

In some embodiments, the stimulus circuit 114 applies the abovementioned stimulus signal 120 to the battery 118. The stimulus signal 120 includes information for a periodic signal having a stimulus frequency F_{STML}. The sampling circuit 116 synchronously samples the abovementioned battery-related voltage and battery-related current at the sampling frequency F_{SMP} to obtain a set of voltage values V_{SMP} and a set of current values I_{SMP}. The processing unit 112 can determine an imaginary part X_{STML} of an impedance of the battery 118 based on the voltage values V_{SMP} and current values I_{SMP}. For example, the processing unit 112 can calculate a complex impedance Z_{STML} of the battery 118 based on the voltage values V_{SMP} and current values I_{SMP}, and extract the imaginary part X_{STML} from the complex impedance Z_{STML}. The processing unit 112 can further search the first group of datasets and/or the second group of datasets for one or more matched datasets. The frequency value in the matched dataset matches the stimulus frequency F_{STML}. The imaginary impedance value in the matched dataset matches the imaginary part X_{STML} of the impedance of the battery 118. The processing unit 112 can further determine a reference value S_{REF} of the SOC of the battery 118 based on the SOC value in the matched dataset. In some embodiments, a first value “matches” a second value if: (a) the first value equals to the second value; (b) the difference between the first and second values is less than a predetermined reference; or (c) the first value is the closest to the second value from among a defined set of values.

For example, the stimulus signal 120 can be a sinusoidal signal (or a DC-biased sinusoidal signal) having a frequency F_{STML}. The processing unit 112 can set the frequency F_{STML} of the stimulus signal 120 to a frequency value that is included in the lookup table 104 or 106. The processing unit 112 can further determine the imaginary part X_{STML} of the battery's impedance corresponding to the frequency F_{STML}. In an embodiment, the processing unit 112 can search the lookup table 104 or 106 for a dataset that has a frequency value equal to the frequency F_{STML} and has an imaginary impedance value closest to the imaginary part X_{STML}. Such a dataset is a matched dataset. The processing unit 112 can determine that the abovementioned reference value S_{REF} is equal to the SOC value in this dataset. In another embodiment, the processing unit 112 can search the lookup table 104 or 106 for a first matched dataset (F_{STML}, X₀, S₀) and a second matched dataset (F_{STML}, X₁, S₁) that have imaginary impedance values X₀ and X₁ closest to the imaginary part X_{STML}. The first matched dataset (F_{STML}, X₀, S₀) has a frequency value equal to the frequency F_{STML}, the imaginary impedance value X₀, and an SOC value S₀. The second matched dataset (F_{STML}, X₁, S₁) has a frequency value equal to the frequency F_{STML}, the imaginary impedance value X₁, and an SOC value S₁. The value of the imaginary part X_{STML} is within the range between X₀ and X₁. In one such embodiment, the processing unit 112 can determine the abovementioned reference value S_{REF} using one-dimensional linear interpolation. For example, the reference value S_{REF} can be obtained based on the following equation:

$${S}_{REF} = \frac{{S}_{1} - {S}_{0}}{{X}_{1} - {X}_{0}} * ( {X}_{STML} - {X}_{0} ) + {S}_{0} .$$

For another example, the stimulus signal 120 can be a square-wave signal including multiple frequency components. Each of the frequency components can be represented by a sinusoidal signal having a corresponding frequency. The processing unit 112 can select a frequency F_{STML} (e.g., less than 10 Hz or 4 Hz) from the frequency components and determine an imaginary part X_{STML} of the battery's impedance corresponding to the frequency F_{STML}. In an embodiment, the lookup table 104 or 106 includes the value of the selected frequency F_{STML}. The processing unit 112 may search the lookup table 104 or 106 for one or two matched datasets using methods similar to those mentioned above. In another embodiment, the lookup table 104 or 106 does not include the value of the selected frequency F_{STML}. The processing unit 112 may search the lookup table 104 or 106 for frequency values F₀ and F₁ closest to the frequency F_{STML} and imaginary impedance values X₀ and X₁ closest to the imaginary part X_{STML} to obtain four matched datasets, e.g., represented by (F₀, X₀, S_{F0X0}), (F₁, X₀, S_{F1X0}), (F₀, X₁, S_{F0X1}), and (F₁, X₁, S_{F1X1}), respectively. The processing unit 112 may perform two-dimensional linear interpolation to obtain the reference value S_{REF} based on the values in the four matched datasets.

Additionally, in some embodiments, each dataset of the first and second group of datasets further includes a temperature value. The sampling circuit 116 can also measure temperature of the battery 118. The temperature value in the matched dataset matches the temperature of the battery 118. In these embodiments, the processing unit 112 may search the lookup table 104 or 106 for one or more matched datasets and perform one-dimensional linear interpolation, two-dimensional linear interpolation, or three-dimensional linear interpolation to obtain the reference value S_{REF} based on the one or more matched datasets. Detailed explanations for one-dimensional linear interpolation, two-dimensional linear interpolation, and three-dimensional linear interpolation are available in the known art and so are not included herein.

Although FIG. 3 and FIG. 4 show that the stimulus circuit 114 is capable of varying the frequency F_{STML} carried in the stimulus signal 120 over a range from 1 Hz to more than 1000 HZ, this does not necessarily mean that the stimulus circuit 114 is required to vary the frequency F_{STML} over the entire range for the processing unit 112 to determine the reference value S_{REF} of the SOC. In some embodiments, the processing unit 112 can control the stimulus circuit 114 to set the frequency F_{STML} to one or more preset frequency values that are less than 10 Hz or 4 Hz. Based on the one or more preset frequency values, the processing unit 112 can determine the reference value S_{REF} of the SOC.

In some embodiments, the battery monitoring system 100 also estimates the SOC of the battery 118 using a “regular” method (e.g., a coulomb integration method combined with an open-circuit voltage method) to obtain a “present value” S_{PST} of the battery's SOC (the present value refers to a value of the battery's SOC based on the values of the battery's parameters at a particular point in time). Detailed explanations for the coulomb integration method combined with the open-circuit voltage method are available in the known art and so are not included herein. The processing unit 112 can compare the reference value S_{REF} with the present value S_{PST}. If the reference value S_{REF} is equal to or approximately equal to the present value S_{PST}, the processing unit 112 may determine that the battery 118 is in a healthy condition and that the present value S_{PST} reliably reflects the actual SOC of the battery 118. If a difference between the reference value S_{REF} and the present value S_{PST} is greater than a first predetermined threshold and less than a second predetermined threshold, the processing unit 112 may determine that the battery 118 remains healthy but exhibits moderate degradation. The processing unit 112 may perform a calibration process to calibrate the present value S_{PST}. For example, the processing unit 112 may calibrate a parameter of the battery 118 (e.g., a full-charge capacity, an end-of-discharge remaining capacity, or the like) and recalculate the present value S_{PST} based on the calibrated parameter. The processing unit 112 may also update parameter values in an SOC versus open-circuit voltage lookup table for the battery 118, and recalculate the present value S_{PST} based on the updated lookup table. As a result, the accuracy of estimating the battery's SOC can be enhanced. If the difference between the reference value S_{REF} and the present value S_{PST} is greater than the second predetermined threshold, the processing unit 112 may determine that the battery 118 may be degraded or faulty. The battery monitoring system 100 may take protective action with respect to the battery 118 and/or a device powered by the battery 118, such as limiting operation or powering off the device. Compared to the conventional EIS methods that apply AC signals across a wide frequency range to generate EIS plots and analyze their patterns, an embodiment of the present invention that determines an imaginary part X_{STML} of the battery's impedance at a preset or selected frequency F_{STML}, and that determines a reference value S_{REF} based on X_{STML} and F_{STML}, may require fewer computing resources and therefore reduce overall system power consumption.

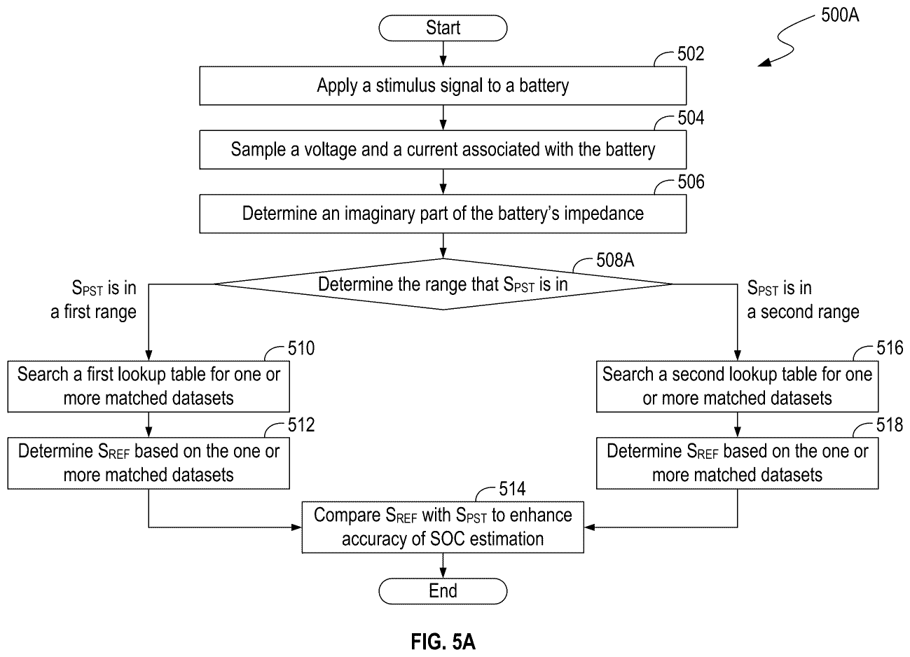

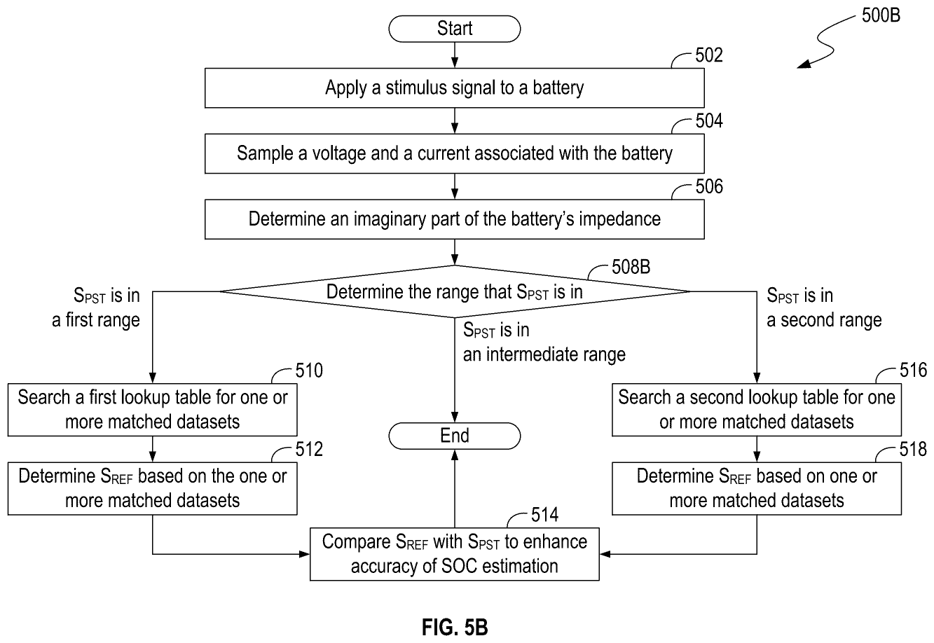

FIG. 5A illustrates a flowchart 500A of an example of a method for monitoring an SOC of the battery 118, in an embodiment of the present invention. Although specific steps are disclosed in FIG. 5A, such steps are examples. That is, the present invention is well suited to performing various other steps or variations of the steps recited in FIG. 5A. FIG. 5A is described in combination with FIG. 1, FIG. 2, FIG. 3, and FIG. 4.

As shown in FIG. 5A, at step 502, the stimulus circuit 114 applies a stimulus signal 120 to the battery 118. At step 504, the sampling circuit 116 synchronously samples a voltage and a current associated with the battery 118 (e.g., the abovementioned battery-related voltage and battery-related current). At step 506, based on the sampled values of the voltage and current, the processing unit 112 determines an imaginary part X_{STML} of the battery's impedance corresponding to a stimulus frequency F_{STML}, e.g., less than 4 Hz, carried in the stimulus signal 120.

At step 508A, the battery monitoring system 100 determines the range that a present value S_{PST} of the SOC of the battery 118 is in. More specifically, in an embodiment, the battery monitoring system 100 can estimate a present value S_{PST} of the SOC of the battery 118 using a regular method, e.g., the coulomb integration method combined with the open-circuit voltage method. The processing unit 112 determines whether the present value S_{PST} is a first range or a second range. For example, the first range can be [0%, 50%], and the second range can be (50%, 100%]. More specifically, the SOC value in the first range can be equal to or greater than 0% and equal to or less 50%. The SOC value in the second range can be greater than 50% and equal to or less than 100%. If the present value S_{PST} is the first range, the flowchart 500A goes to step 510; otherwise, the flowchart 500A goes to step 516.

At step 510, the processing unit 112 searches the first group of datasets in the first lookup table 104 for one or more matched datasets. At step 512, the processing unit 112 determines a reference value S_{REF} of the battery's SOC based on the one or more matched datasets. At step 514, the processing unit 112 compares the reference value S_{REF} with the present value S_{PST} to enhance the accuracy of the SOC estimation.

At step 508A, if the present value S_{PST} is the second range, the flowchart 500A goes to step 516. At step 516, the processing unit 112 searches the second group of datasets in the second lookup table 106 for one or more matched datasets. At step 518, the processing unit 112 determines the reference value S_{REF} of the battery's SOC based on the one or more matched datasets. Following step 518, the flowchart 500A goes to step 514. Following step 514, the flowchart 500A ends.

FIG. 5B illustrates a flowchart 500B of an example of a method for monitoring the battery's SOC, in another embodiment of the present invention. Although specific steps are disclosed in FIG. 5B, such steps are examples. That is, the present invention is well suited to performing various other steps or variations of the steps recited in FIG. 5B. FIG. 5B is described in combination with FIG. 1, FIG. 2, FIG. 3, FIG. 4, and FIG. 5A. The flowchart 500B is similar to the flowchart 500A except that, at step 508B in FIG. 5B, the processing unit 112 determines whether the present value S_{PST} is in a first range, an intermediate range, or a second range. For example, the first range can be [0%, 40%], the intermediate range can be (40%, 60%), and the second range can be [60%, 100%]. For another example, the first range can be [0%, 45%], the intermediate range can be (45%, 65%), and the second range can be [65%, 100%]. SOC values in the intermediate range are greater than those in the first range and less than those in the second range. At step 508B, if the present value S_{PST} is in the intermediate range, the flowchart 500B ends.

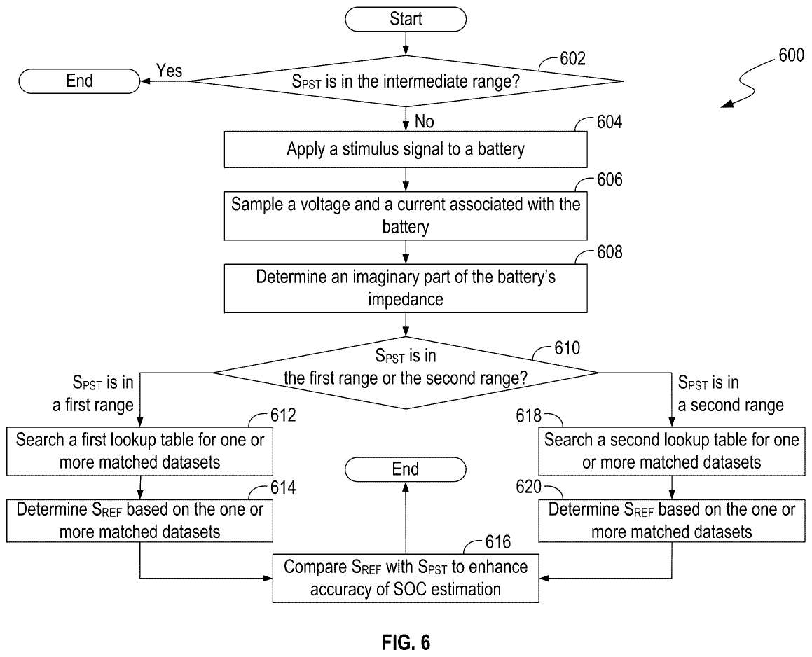

FIG. 6 illustrates a flowchart 600 of an example of a method for monitoring the battery's SOC, in another embodiment of the present invention. Although specific steps are disclosed in FIG. 6, such steps are examples. That is, the present invention is well suited to performing various other steps or variations of the steps recited in FIG. 6. FIG. 6 is described in combination with FIG. 1, FIG. 2, FIG. 3, FIG. 4, FIG. 5A, and FIG. 5B.

As shown in FIG. 6, at step 602, the processing unit 112 estimates a present value S_{PST} of the battery's SOC and determines whether the present value S_{PST} is in the intermediate range. If the present value S_{PST} is in the intermediate range, the flowchart 600 ends; otherwise, the flowchart goes to step 604.

At step 604, the stimulus circuit 114 applies a stimulus signal 120 to the battery 118. At step 606, the sampling circuit 116 synchronously samples a voltage and a current associated with the battery 118 (e.g., the abovementioned battery-related voltage and battery-related current). At step 608, based on the sampled values of the voltage and current, the processing unit 112 determines an imaginary part X_{STML} of the battery's impedance corresponding to a stimulus frequency F_{STML}, e.g., less than 4 Hz, carried in the stimulus signal 120. At step 610, the processing unit 112 determines whether the present value S_{PST} is in a first range or a second range. If the present value S_{PST} is in the first range, the flowchart 600 goes to step 612; otherwise, the flowchart 600 goes to step 618.

At step 612, the processing unit 112 searches the first lookup table 104 for one or more matched datasets. At step 614, the processing unit 112 determines a reference value S_{REF} of the battery's SOC based on the one or more matched datasets. At step 616, the processing unit 112 compares the reference value S_{REF} (from step 614) with the present value S_{PST} to enhance the accuracy of the SOC estimation. At step 618, the processing unit 112 searches the second lookup table 106 for one or more matched datasets. At step 620, the processing unit 112 determines the reference value S_{REF} of the battery's SOC based on the one or more matched datasets. Following step 620, the flowchart 600 goes to step 616 and the processing unit 112 compares the reference value S_{REF} (from step 620) with the present value S_{PST} to enhance the accuracy of the SOC estimation. Following step 616, the flowchart 600 ends.

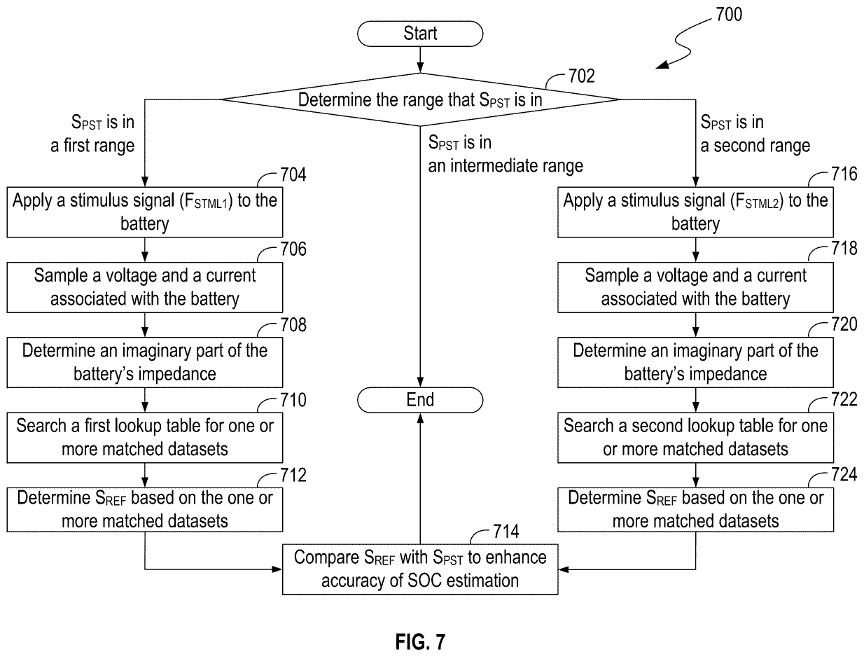

FIG. 7 illustrates a flowchart 700 of an example of a method for monitoring the battery's SOC, in another embodiment of the present invention. Although specific steps are disclosed in FIG. 7, such steps are examples. That is, the present invention is well suited to performing various other steps or variations of the steps recited in FIG. 7. FIG. 7 is described in combination with FIG. 1, FIG. 2, FIG. 3, FIG. 4, FIG. 5A, FIG. 5B, and FIG. 6.

As shown in FIG. 7, at step 702, the processing unit 112 estimates a present value S_{PST} of the battery's SOC and determines whether the present value S_{PST} is in a first range, an intermediate range, or a second range. If the present value S_{PST} is in the intermediate range, the flowchart 700 ends. If the present value S_{PST} is in the first range, the flowchart 700 goes to step 704. If the present value S_{PST} is in the second range, the flowchart 700 goes to step 716.

At step 704, the stimulus circuit 114 applies a stimulus signal 120 to the battery 118. The stimulus signal 120 can include a sinusoidal signal or a DC-biased sinusoidal signal. The stimulus circuit 114 can set a stimulus frequency of the sinusoidal signal to F_{STML1}, e.g., less than 10 Hz.

At step 706, the sampling circuit 116 synchronously samples a voltage and a current associated with the battery 118 (e.g., the abovementioned battery-related voltage and battery-related current). At step 708, based on the sampled values of the voltage and current, the processing unit 112 determines an imaginary part X_{STML} of the battery's impedance corresponding to the stimulus frequency F_{STML1}. At step 710, the processing unit 112 searches the first lookup table 104 for one or more matched datasets. At step 712, the processing unit 112 determines a reference value S_{REF} of the battery's SOC based on the one or more matched datasets. At step 714, the processing unit 112 compares the reference value S_{REF} (from step 712) with the present value S_{PST} to enhance the accuracy of the SOC estimation.

At step 716, the stimulus circuit 114 applies a stimulus signal 120 to the battery 118. The stimulus signal 120 can include a sinusoidal signal or a DC-biased sinusoidal signal. The stimulus circuit 114 can set a stimulus frequency of the sinusoidal signal to F_{STML2}, e.g., less than 4 Hz.

At step 718, the sampling circuit 116 synchronously samples a voltage and a current associated with the battery 118 (e.g., the abovementioned battery-related voltage and battery-related current). At step 720, the processing unit 112 determines an imaginary part X_{STML} of the battery's impedance corresponding to the stimulus frequency F_{STML2}. At step 722, the processing unit 112 searches the second lookup table 106 for one or more matched datasets. At step 724, the processing unit 112 determines a reference value S_{REF} of the battery's SOC based on the one or more matched datasets. Following step 724, the flowchart 700 goes to step 714 and the processing unit 112 compares the reference value S_{REF} (from step 724) with the present value S_{PST} to enhance the accuracy of the SOC estimation. Following step 714, the flowchart 700 ends.

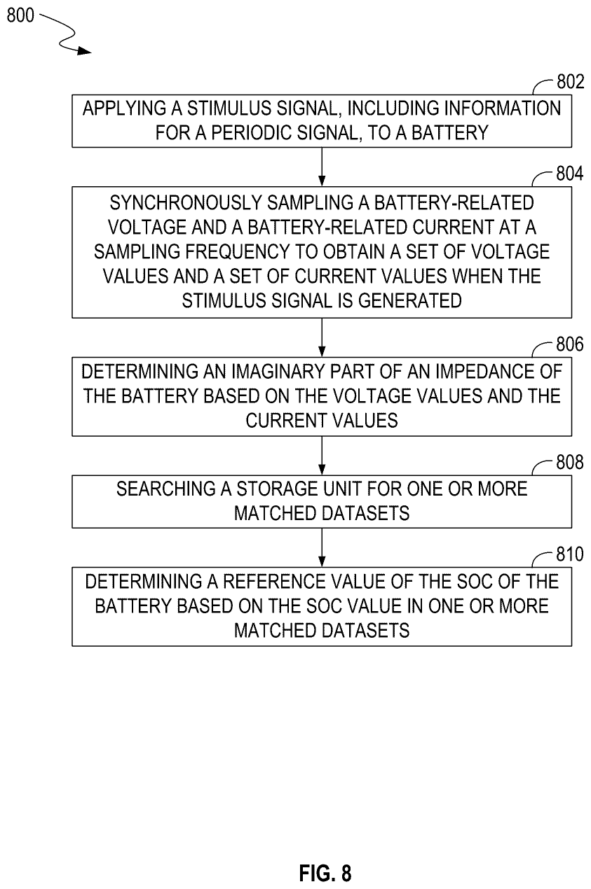

FIG. 8 illustrates a flowchart 800 of an example of a method for monitoring an SOC of a battery, in an embodiment of the present invention. FIG. 8 is described in combination with FIG. 1, FIG. 2, FIG. 3, FIG. 4, FIG. 5A, FIG. 5B, FIG. 6, and FIG. 7.

As shown in FIG. 8, at step 802, the stimulus circuit 114 applies a stimulus signal 120 to the battery 118. The stimulus signal 120 includes information for a periodic signal, e.g., a sinusoidal signal, a DC-biased sinusoidal signal, a multisine signal, a DC-biased multisine signal, a square-wave signal, a PRBS signal, a chirp signal, white noise, or the like, that has a stimulus frequency F_{STML}.

At step 804, the sampling circuit 116 synchronously samples a battery-related voltage and a battery-related current at a sampling frequency F_{SMP} to obtain a set of voltage values V_{SMP} and a set of current values I_{SMP}. The battery-related voltage and the battery-related current are associated with the battery 118 and vary in response to the stimulus signal 120.

At step 806, the processing unit 112 determines an imaginary part X_{STML} of an impedance Z_{STML} of the battery 118, corresponding to the stimulus frequency F_{STML}, based on the voltage values V_{SMP} and the current values I_{SMP}.

At step 808, the processing unit 112 searches the storage unit 102, e.g., a non-transitory machine-readable storage medium, for one or more matched datasets. More specifically, the storage unit 102 stores multiple datasets. Each dataset of the multiple datasets includes a frequency value, an imaginary impedance value, and an SOC value. The frequency value in the matched dataset matches (e.g., is selected or identified as a match for) the stimulus frequency F_{STML} carried in the stimulus signal 120. The imaginary impedance value in the matched dataset matches (e.g., is selected or identified as a match for) the imaginary part X_{STML} of the impedance Z_{STML}. As described previously herein, a first value is selected or identified as a match for a second value if: (a) the first value equals to the second value; (b) the difference between the first and second values is less than a predetermined reference; or (c) the first value is the closest to the second value from among a defined set of values.

At step 810, the processing unit 112 determines a reference value S_{REF} of the SOC of the battery 118 based on the SOC value in the matched datasets. In some embodiments, the processing unit 112 can use the reference value S_{REF} to enhance the accuracy of estimating the battery's SOC and evaluate the battery's SOH.

While the foregoing description and drawings represent embodiments of the present invention, it will be understood that various additions, modifications, and substitutions may be made therein without departing from the spirit and scope of the principles of the present invention as defined in the accompanying claims. One skilled in the art will appreciate that the invention may be used with many modifications of form, structure, arrangement, proportions, materials, elements, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being indicated by the appended claims and their legal equivalents, and not limited to the foregoing description.

What is claimed is:

1. A battery monitoring system operable for monitoring a state of charge (SOC) of a battery, said battery monitoring system comprising:
a stimulus circuit configured to apply a stimulus signal to said battery, wherein said stimulus signal comprises information for a periodic signal having a stimulus frequency;
a sampling circuit configured to synchronously sample a battery-related voltage and a battery-related current at a sampling frequency to obtain a plurality of voltage values and a plurality of current values, wherein said sampling frequency is higher than said stimulus frequency, and wherein said battery-related voltage and said battery-related current are associated with said battery and vary in response to said stimulus signal;
a non-transitory machine-readable storage medium configured to store a plurality of datasets, wherein each dataset of said plurality of datasets comprises a frequency value, an imaginary impedance value, and an SOC value; and
a processing unit, coupled to said stimulus circuit, said sampling circuit, and said non-transitory machine-readable storage medium, and configured to determine an imaginary part of an impedance of said battery based on said voltage values and said current values, and to search said plurality of datasets for at least one matched dataset, wherein the frequency value in said least one matched dataset is selected as a match for said stimulus frequency, and the imaginary impedance value in said least one matched dataset is selected as a match for said imaginary part of said impedance of said battery, and wherein said processing unit is further configured to determine a reference value of said SOC of said battery based on the SOC value in said at least one matched dataset.

2. The battery monitoring system of claim 1, wherein said each dataset further comprises a temperature value, wherein said sampling circuit is further configured to measure temperature of said battery, and wherein the temperature value in said least one matched dataset is selected as a match for said temperature of said battery.

3. The battery monitoring system of claim 1, wherein said impedance of said battery is given by: Z=a+bi, where “Z” represents said impedance of said battery, “a” represents a real part of said impedance, “b” represents said imaginary part of said impedance, and “i” represents the imaginary unit.

4. The battery monitoring system of claim 1, wherein said processing unit is further configured to calculate said impedance of said battery based on said voltage values and said current values, and to extract said imaginary part from said impedance.

5. The battery monitoring system of claim 1, wherein said plurality of datasets comprises a first group of datasets and a second group of datasets, wherein SOC values in said first group of datasets are in a first range, and SOC values in said second group of datasets are in a second range, and wherein the minimum SOC value of said second range is greater the maximum SOC value of said first range.

6. The battery monitoring system of claim 5, wherein said first group of datasets comprises a first dataset and a second dataset, the imaginary impedance value in said first dataset is greater than the imaginary impedance value in said second dataset, and the SOC value in said first dataset is less than the SOC value in said second dataset;
and wherein said second group of datasets comprises a third dataset and a fourth dataset, the imaginary impedance value in said third dataset is greater than the imaginary impedance value in said fourth dataset, and the SOC value in said third dataset is greater than the SOC value in said fourth dataset.

7. The battery monitoring system of claim 6, wherein said battery monitoring system is configured to estimate a present value of said SOC of said battery and determine which range of a plurality of ranges said present value is in, wherein said plurality of ranges comprises said first and second ranges, and wherein said processing unit is further configured to:
search said first group of datasets for said at least one matched dataset if said present value is in said first range; and
search said second group of datasets for said at least one matched dataset if said present value is in said second range.

8. The battery monitoring system of claim 1, wherein said stimulus signal comprises a stimulus current, wherein said battery-related current comprises a current of said stimulus current and a battery current of said battery, and wherein said battery-related voltage comprises a battery voltage of said battery.

9. The battery monitoring system of claim 1, wherein said stimulus signal comprises a stimulus voltage, wherein said battery-related voltage comprises a voltage of said stimulus voltage and a battery voltage of said battery, and wherein said battery-related current comprises a battery current of said battery.

10. The battery monitoring system of claim 1, wherein said periodic signal comprises a sinusoidal signal.

11. A method for monitoring a state of charge (SOC) of a battery, said method comprising:
applying, using a stimulus circuit, a stimulus signal to said battery, wherein said stimulus signal comprises information for a periodic signal having a stimulus frequency;
synchronously sampling, using a sampling circuit, a battery-related voltage and a battery-related current at a sampling frequency to obtain a plurality of voltage values and a plurality of current values, wherein said sampling frequency is higher than said stimulus frequency, and wherein said battery-related voltage and said battery-related current are associated with said battery and vary in response to said stimulus signal;
determining, using a processing unit coupled to said stimulus circuit and said sampling circuit, an imaginary part of an impedance of said battery based on said voltage values and said current values;
searching, using said processing unit, a non-transitory machine-readable storage medium for at least one matched dataset, wherein said non-transitory machine-readable storage medium stores a plurality of datasets that comprises said at least one matched dataset, wherein each dataset of said plurality of datasets comprises a frequency value, an imaginary impedance value, and an SOC value, wherein the frequency value in said least one matched dataset is selected as a match for said stimulus frequency, and the imaginary impedance value in said least one matched dataset is selected as a match for said imaginary part of said impedance of said battery; and
determining a reference value of said SOC of said battery based on the SOC value in said at least one matched dataset.

12. The method of claim 11, further comprising:
measuring temperature of said battery,
wherein said each dataset further comprises a temperature value, and wherein the temperature value in said at least one matched dataset is selected as a match for said temperature of said battery.

13. The method of claim 12, wherein said plurality of datasets comprises a first group of datasets and a second group of datasets, wherein SOC values in said first group of datasets are in a first range, and SOC values in said second group of datasets are in a second range, and wherein the minimum SOC value of said second range is greater the maximum SOC value of said first range.

14. The method of claim 13, wherein said first group of datasets comprises a first dataset and a second dataset, the imaginary impedance value in said first dataset is greater than the imaginary impedance value in said second dataset, and the SOC value in said first dataset is less than the SOC value in said second dataset;
and wherein said second group of datasets comprises a third dataset and a fourth dataset, the imaginary impedance value in said third dataset is greater than the imaginary impedance value in said fourth dataset, and the SOC value in said third dataset is greater than the SOC value in said fourth dataset.

15. The method of claim 14, further comprising:
estimating a present value of said SOC of said battery;
determining which range of a plurality of ranges said present value is in, wherein said plurality of ranges comprises said first and second ranges;
searching said first group of datasets for said at least one matched dataset if said present value is in said first range; and
searching said second group of datasets for said at least one matched dataset if said present value is in said second range.

16. The method of claim 11, wherein said impedance of said battery is given by: Z=a+bi, where “Z” represents said impedance of said battery, “a” represents a real part of said impedance, “b” represents said imaginary part of said impedance, and “i” represents the imaginary unit.

17. The method of claim 11, wherein said determining said imaginary part of said impedance of said battery comprises:
calculating said impedance of said battery based on said voltage values and said current values; and
extracting said imaginary part from said impedance.

18. The method of claim 11, wherein said stimulus signal comprises a stimulus current, wherein said battery-related current comprises a current of said stimulus current and a battery current of said battery, and wherein said battery-related voltage comprises a battery voltage of said battery.

19. The method of claim 11, wherein said stimulus signal comprises a stimulus voltage, wherein said battery-related voltage comprises a voltage of said stimulus voltage and a battery voltage of said battery, and wherein said battery-related current comprises a battery current of said battery.

20. The method of claim 11, wherein said periodic signal comprises a sinusoidal signal.
